(19) United States
(12) Patent Application Publication
(10) Pub. No.: US 2022/0051956 A1
(43) Pub. Date: Feb. 17, 2022

(54) AIR CAVITY PACKAGE WITH IMPROVED CONNECTIONS BETWEEN COMPONENTS

(71) Applicant: RJR Technologies, Inc., Phoenix, AZ (US)

(72) Inventors: Alex Elliott, Phoenix, AZ (US); William Strom, Phoenix, AZ (US)

(73) Assignee: RJR Technologies, Inc., Phoenix, AZ (US)

(21) Appl. No.: 17/274,887

(22) PCT Filed: Sep. 6, 2019
(86) PCT No.: PCT/IB2019/057546

§ 371 Date: Mar. 10, 2021

Related U.S. Application Data
(60) Provisional application No. 62/729,707, filed on Sep. 11, 2018.

(51) Int. Cl. H01L 23/10; H01L 21/48

(52) U.S. Cl. CPC H01L 23/10; H01L 21/481

(57) ABSTRACT

An air cavity package with one or more dovetail recesses configured with a first recess and a coincident second recess. The first recess has a first depth and the second recess has a second depth. The first recess has a lower width and an upper width smaller than the first lower width creating a dovetail shape. Individual dovetail recesses are created by creating a first recess in the flange at a first width and depth. A second recess with a second width and second depth and coincident with the first recess is pressed into the flange. The second width is greater than the first width and the second depth is smaller than the first depth. Pressing the second recess causes the first width at an upper portion to decrease, causing the first recess to develop a dovetail shape.

### CROSS REFERENCE TO RELATED APPLICATIONS

This Patent Application is a national stage entry application claiming priority under 35 U.S.C. § 371(c) to PCT/IB2019/057546, entitled “AIR CAVITY PACKAGE WITH IMPROVED CONNECTIONS BETWEEN COMPONENTS,” filed Sep. 6, 2019, which is related to and claims priority under 35 U.S.C. § 119(e) to U.S. Provisional Patent Application No. 62/729,707, entitled “AIR CAVITY PACKAGE WITH IMPROVED CONNECTIONS BETWEEN COMPONENTS,” filed Sep. 11, 2018.

### FIELD OF THE INVENTION

The present disclosure relates generally to air cavity packages with structure and mechanisms that improve connections between components of the air cavity packages.

### BACKGROUND

Electronic devices are ubiquitous in consumer and commercial products and devices throughout the world. Many include circuitry which are often comprised of materials such as silicon, gallium arsenide, and other similar “semi-conductor” materials, and are commonly referred to in industry as “dies” or “chips.” Any given die may be capable of containing a multitude of circuit elements for performing various functions. In use, these dies are often incorporated into packages known as air cavity packages (ACPs) generally comprised of a housing surrounding a volume for containing the dies and various electrical components that provide for a variety of functions. The ACP housing typically comprises a flange or base, one more insulative sidewalls attached to the flange, and a leadframe extending therethrough. Inside the housing, the leadframe is bonded to the die. Many protective housings comprise two pieces, including a set of sidewalls and a lid, although some housings are molded as one-piece assemblies.

There are a variety of conventionally known ways to assemble the components of ACPs such as by mechanically bonding using adhesives and epoxies, mechanical fasteners, and the like. However, some of these methods, such as adhesives and expoxies can fail by, for example, separation or delamination. Conventional techniques to improve these bonds require more processing steps of the components, including more complex geometries (e.g., long channels created in the flange) and mechanical and/or chemical treatment of the surfaces to which the adhesives are applied, creating extra processing steps and cost. Thus, there is a need for structure and mechanisms that improve the strength and ability to affix components of ACPs to one another, without significantly impacting processing and related cost.

### SUMMARY

While the ways in which the present disclosure address the disadvantages of the prior art will be discussed in greater detail below, in general, the present disclosure is directed to ACPs with one or more individual dovetail recesses (i.e., mold locks) for improving the connection of the components of ACPs. ACPs of the present disclosure comprise a flange, a leadframe, and a sidewall and/or a lid. In accordance with various aspects of the present disclosure, the sidewalls may comprise various types of polymers such as a liquid crystal polymer (LCP) and other suitable materials.

In accordance with the present disclosure, the flange may have one or more individual dovetail recesses proximate to the area where the sidewall and flange connect. The individual dovetail recesses function as mold locks. Each dovetail recess is configured with a first recess and a second recess coincident with the first recess. The first recess has a first depth and the second recess has a second depth which is less than the first depth. The first recess has a first lower width and a first upper width which is smaller than the first lower width thus creating a dovetail shape which allows the molded material of the sidewall to more securely lock within the dovetail recess of the flange after curing because the lower width of the material within the dovetail recess is greater than the first upper width of the dovetail recess.

In accordance with the present disclosure, the dovetail recess is created by first creating a first recess in the flange at a first width and depth. Next, a second recess with a second width and second depth and which is coincident with the first recess is pressed into the flange. The second width it greater than the first width and the second depth is smaller than the first depth. Thus, the pressing of the second recess causes the first width at an upper portion of the first recess to decrease and create an overhang, causing the first recess to develop a dovetail shape.

### BRIEF DESCRIPTION OF THE DRAWINGS

The accompanying drawings are included to provide a further understanding of the disclosure and are incorporated in and constitute a part of this specification, illustrate embodiments of the disclosure, and together with the description serve to explain the principles of the disclosure, wherein like numerals denote like elements and wherein:

FIG. 1 is a cross-sectional view of an air cavity package with a flange with individual dovetail recesses, leadframes, sidewall and lid;

FIG. 2 is a close-up cross-sectional view of a portion of a flange with a dovetail recess formed therein;

FIG. 3A a close-up cross-sectional view of a portion of a flange with a first recess prior to being shaped into a dovetail;

FIG. 3B a close-up cross-sectional view of the portion of the flange of FIG. 3A with a press forming a second recess therein;

FIG. 3C a close-up cross-sectional view of the portion of the flange of FIG. 3A after the press has been removed showing the first recess with a dovetail shape; and

FIG. 4 is a top view of an air cavity package flange with a plurality of individual dovetail recesses proximate the location of attachment of an air cavity package sidewall.

### DETAILED DESCRIPTION

Persons skilled in the art will readily appreciate that various aspects of the present disclosure can be realized by any number of structures, components, and systems configured to perform various functions disclosed herein. Stated differently, other such structures, components, and systems can be incorporated herein to perform the intended functions. It should also be noted that the accompanying drawing figures referred to herein are not all necessarily drawn to scale and may be exaggerated to illustrate various aspects of the present disclosure, and in that regard, the drawing figures should not be construed as limiting.

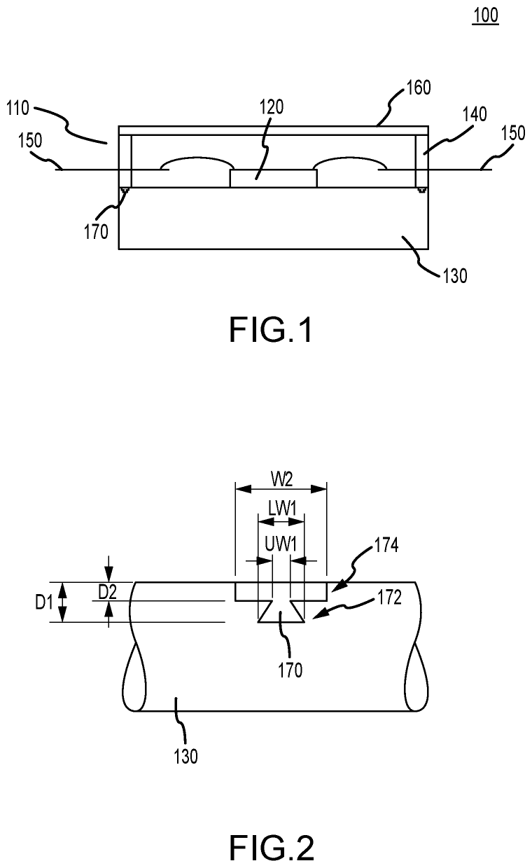

With reference to FIG. 1, ACPs 100 in accordance with the present disclosure typically comprise a housing 110 surrounding a die 120. The housing 110 typically comprises a flange 130, an insulative sidewall 140 attached to the flange 130, and a leadframe 150 extending therethrough. Inside the housing 110, the leadframe 150 is bonded to the die 120. In some embodiments such as that illustrated in FIG. 1, the housing 110 may further comprise a lid 160 attached to the sidewall 140, though some housings 110 may be molded as one-piece assemblies.

As noted above, a variety of conventionally known ways to assemble the components of ACPs 100 exist such as by using adhesives and epoxies. This assembly includes attaching the sidewalls 140 to the flange 130, and potentially, any number of other components of the ACP 100 that need to be attached to complete ACP 100. However, as also noted above, adhesives and expoxies can fail. Thus, in accordance with the present disclosure, mechanisms for improving the connection between components are provided.

For example, with reference to FIG. 2, a portion of a flange 130 with an individual dovetail recess 170 therein is shown. As used herein, “individual” means each dovetail recess 170 is formed at a single defined point, not an elongated channel or groove. The dovetail recess 170 is configured with a first recess 172 and a second recess 174 coincident with the first recess 172. The first recess has a first depth D1 and the second recess 174 has a second depth D2 which is less than the first depth D1.

The shape of the first and second recesses 172, 174 may vary. For example, the first and second recesses 172, 174 may be formed as ellipsoid (e.g., circular, oval, etc.), polygonal (e.g., rectangular, octagonal, etc.), or other shape having an individual dovetail profile, as described in detail below. Additionally, the first recess 172 and the second recess 174 may have shapes that differ from one another. Additionally, though the description herein is directed largely at a dovetail recess 170 in a portion of a flange 130, it should be appreciated that multiple individual dovetail recesses 170 may be included in one flange 130.

The first recess 172 has a first lower width LW1 and a first upper width UW1 which is smaller than the first lower width LW1. The shape of the first recess 172 is thus one commonly known as a “dovetail” which provides an “overhang.” Because of this overhang, when the sidewall 140 is molded to and fills in the first recess 172, because the portion of the sidewall 140 located proximate the first lower width LW1 of the first recess 172 is greater than the first upper width UW1 of the first recess 172, the sidewall 140 is more securely connected to the flange.

In accordance with the present disclosure, the second recess 174 has a second depth D2 and a second width W2 that is generally the same along the second depth D2 (though the width may vary based on the application). The second width W2 is greater than either of the first upper width UW1 and the first lower width LW1. The larger width of the second width W2 of the second recess 174 facilitates the formation of the dovetail shape of the first recess 172.

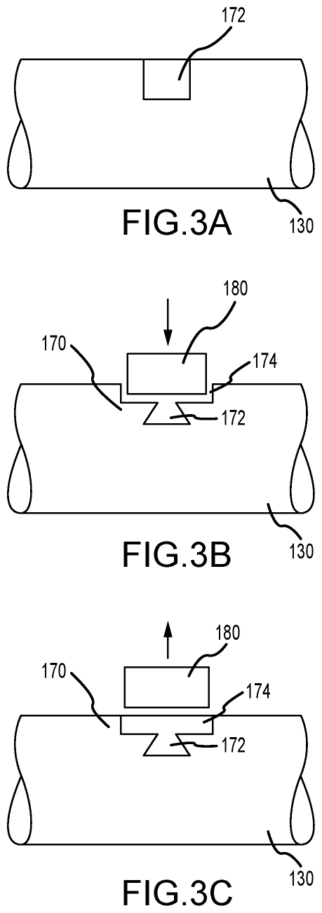

For example, with reference now to FIGS. 3A-C, a portion of a flange 130 is shown. In FIG. 3A, the first recess 172 has been formed in flange 130 with the first depth D1 (FIG. 2). The first recess 172 can be formed in flange 130 by any now known or as yet unknown means. For example, the first recess 172 may be formed by stamping or pressing the first recess 172 into the flange 130. When the first recess 172 is initially formed in the flange 130, it does not have a dovetail shape. Rather, it is the creation of the second recess 174 which creates the dovetail shape. Namely, with reference now to FIG. 3B, a press 180 having the same general shape as the desired shape of second recess 174 is applied to the flange 130 coincident with the first recess 172 (FIG. 3B) and pressed into the flange 130 to the second depth D2 (FIG. 2) to form second recess 174. The pressure of the formation of the second recess 174 causes the material of the flange 130 where the second recess 174 and the first recess 172 meet to fold in or “overhang” at the upper portion of the first recess 172, creating a first upper width UW1 of the first recess 172 that is smaller than the first lower width LW1 of the first recess 172, and upon removal of the press 180 (FIG. 3C), a dovetail shape of the first recess 172 is created, which assists in locking the sidewall 140 to the flange 130 when the material of the sidewall 140 is cured.

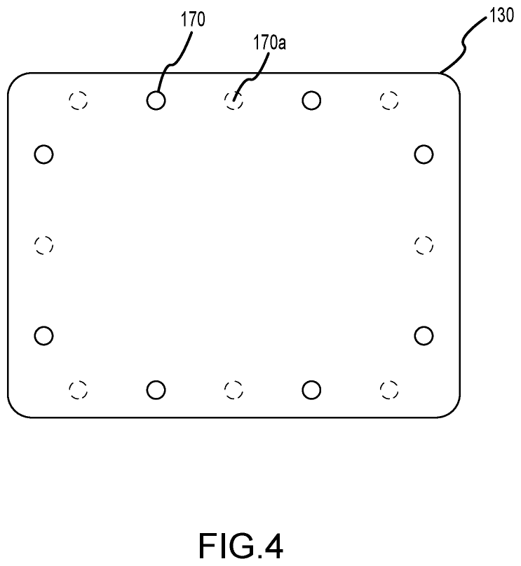

In accordance with the present disclosure, multiple dovetail recesses 170 may be used to secure the sidewall 140 to the flange 130. For example, with reference to FIG. 4, a top view of a flange 130 with multiple dovetail recesses 170 around a perimeter of the flange 130 proximate to where the sidewall 140 is attached to the flange 130 is shown. In accordance with the present disclosure, the number of and location of the dovetail recesses 170 can be varied depending on the requirements of the ACP 100. For example, the illustrated flange 130 has eight dovetail recesses 170. However, additional dovetail recesses 170a (shown in phantom) can be provided by simply adding more recesses. Similarly, the number of dovetail recesses 170 can be reduced as necessary. Moreover, as those skilled in the art will appreciate, the locations of the dovetail recesses may be varied as well. For example, it may be desirable to space the dovetail recesses 170 apart from one another differently depending on the particular application. Stated otherwise, the number and placement of individual dovetail recesses 170, 170a is for illustrative purposes only, and the individual dovetail recesses 170 contemplated herein are highly customizable.

Finally, the foregoing description emphasizes particular embodiments and examples of the contemplated disclosure. However, as those skilled in the art will recognize, however, the scope of the present disclosure extends as well to variations and modifications of the above, in terms of materials, operating conditions, operating procedures, and other parameters and their components and of procedures for their assembly.

Likewise, numerous characteristics and advantages have been set forth in the preceding description, including various alternatives together with details of the structure and function of the methods and systems described herein. The disclosure is intended as illustrative only and as such is not intended to be exhaustive. It will be evident to those skilled in the art that various modifications may be made, especially in matters of order, process, structure, elements, components, and arrangement including combinations of the same within the principles of the disclosure, to the full extent indicated by the broad, general meaning of the terms in which the appended claims are expressed. To the extent that these various modifications do not depart from the spirit and scope of the appended claims, they are intended to be encompassed therein.

I claim:

1. A method for creating an individual dovetail recess in a flange of an air cavity package, comprising the steps of:
creating a first recess in the flange having a first width and first depth;
pressing a second recess into the flange, the second recess being coincident with the first recess and having a second width and a second depth, wherein the second width it greater than the first width and the second depth is smaller than the first depth; and
wherein pressing the second recess causes the first width at an upper portion of the first recess to decrease, causing the first recess to develop a dovetail shape.

2. The method of claim 1 wherein the first recess is elliptical.

3. The method of claim 2 wherein the second recess is elliptical.

4. The method of claim 1 wherein the first recess is rectangular.

5. The method of claim 4 wherein the second recess is rectangular.

6. The method of claim 1 wherein a plurality of individual dovetail recesses are created in the flange proximate the location of attachment of an air cavity package sidewall.

7. An air cavity package, comprising a flange having a plurality of individual dovetail recesses about a flange perimeter proximate the location of attachment of an air cavity package sidewall.

8. The air cavity package of claim 7 wherein at least one of the individual dovetail recesses is elliptical.

9. The air cavity package of claim 7 wherein at least one of the individual dovetail recesses is rectangular.
